(19) United States
(12) Patent Application Publication
(10) Pub. No.: US 2006/0103411 A1
(43) Pub. Date: May 18, 2006

(54) Method for measuring thin film transistor array of active matrix display panel

(75) Inventor: Takashi Miyamoto, Hachioji-shi (JP)

Correspondence Address: Paul D. Greeley, Esq.;Ohlandt, Greeley, Ruggiero & Perle, L.L.P., 10th Floor, One Landmark Square, Stamford, CT, 06901-2682, US

(73) Assignee: Agilent Technologies, Inc.

(21) Appl. No.: 11/235,874

(22) Filed: Sep. 27, 2005

(30) Foreign Application Priority Data
Oct. 15, 2004 (JP) 2004-302216

(51) Int. Cl. G01R 31/00

(52) U.S. Cl. 324/770

(57) ABSTRACT

A measurement method, wherein a TFT array, which comprises multiple pixel circuits having a holding capacitor, a switching transistor for connecting data lines to the circuits, and gate lines for controlling the transistor and wherein there are at least first, second, third, and fourth pixel circuits, is subjected to measurement of the charge of the holding capacitor of the first pixel circuit that has passed through a predetermined holding time after charging; charging to the holding capacitor of the still uncharged third pixel circuit; measurement of the charge of the holding capacitor of the second pixel circuit that has passed through a predetermined holding time after charging; charging to the holding capacitor of the still uncharged fourth pixel circuit; measurement of the holding capacitor of the third pixel circuit that has passed through the predetermined holding time after charging; and measurement of the charge of the holding capacitor of the fourth pixel circuit that has passed through the predetermined holding time after charging.

### FIELD OF THE INVENTION

The present invention pertains to a method for measuring the holding properties of a TFT (thin film transistor) array of an active matrix display panel.

### DISCUSSION OF THE BACKGROUND ART

Circuit tests called array tests are performed on each pixel of a TFT array, wherein pixel circuits are formed in matrix form on a panel, for testing an active matrix display panel made from liquid crystals or electroluminesence (EL hereafter) elements (for instance, organic EL elements, and other EL elements). In the present Specification, the TFT array used in the array test can be the TFT array before the liquid crystal, EL element, or other light-emitting material is formed, or the TFT array after these light-emitting materials have been formed. It is generally preferred that defective products be removed before forming expensive pixels in order to reduce manufacturing costs.

Each pixel circuit of the TFT array of these display panels is for the most part composed of pixel-selecting transistors for selecting pixels, a holding capacitor for storing the voltage that is supplied to the pixels, and a pixel drive part for driving the pixels in accordance with the voltage that is supplied.

One of the array tests is a test for examining the holding properties of this holding capacitor. This is a test whereby a predetermined charge is written in the holding capacitor and the remaining charge is read after a predetermined holding time has passed (it is often 16.7 ms of the frame time). Algorithms for reducing the measurement time of holding property tests on TFT arrays of active matrix liquid crystal display panels are shown in FIGS. 13 and 14 and described in paragraphs 49 through 55 of JP Publication Patent 7[1995]-5408, FIGS. 13 and 14, paragraphs 49 through 55.

On the other hand, the newer active matrix liquid crystal display panels have a two-way shift register that corresponds to shift directions of a horizontal or a vertical shift register of the TFT array, as cited in Sony, LCX028BMT (4.6 cm (1.8-inch) Black-and-White LCD Panel) Data Sheet.

The following is a discussion of the method for measuring the holding properties of a holding capacitor of a TFT array of an active matrix display panel comprising control lines to a shift register for pixel selection based on the testing method disclosed in FIG. 13 of JP Publication Patent 7[1995]-5408 as estimated by the inventors.

It should be noted that as in JP Publication Patent 7[1995]-5408, this discussion assumes that writing time Tw to the holding capacitor and reading time Tr are both the same τ.

As shown in FIG. 13, which is a block diagram of a general testing device 1300 estimated by the inventors, a TFT array 1302 comprises an H shift register (horizontal shift register) 1340 for selecting data lines and a V shift register (vertical shift register) 1342 for selecting gate lines. Pixels (represented by 1356, 1358, and 1360) are selected and tested by these shift registers. Each of the shift registers has a clock terminal (CLK_H 1328, CLK_V 1348) and a pulse input terminal (Start_H 1330, Start_V 1346), and these perform a shift operation. An enable terminal (ENB_V) is connected to the V shift register. A charge meter Q 1310 and a variable voltage source 1322 are connected in series to a power source terminal 1324 at the H shift register.

However, as can be easily understood by persons skilled in the art, by means of the measurement method according to FIG. 13 of JP Publication Patent 7[1995]-5408, the holding time Th for pixels where reading and writing are performed must be the same for each pixel; therefore, Tw and Tr must be the same. Nevertheless, when writing time Tw to the holding capacitor and reading time Tr are actually discussed, Tr is generally at least twice Tw, with Tw<Tr; therefore, this algorithm is inefficient, as discussed below.

The measurement method based on the testing device shown in FIG. 13 as estimated by the inventors will be described using the timing chart in FIG. 14. It should be noted that by means of this testing method, all pixels are assigned to multiple pixel groups and tested by each pixel group. This description focuses on the j^{th} pixel group. The holding capacity of the first pixel P_{j,1} is written, that is, charged, over writing time W (that is, Tw in FIG. 13 of JP Publication Patent 7[1995]-5408) from time tₒ, and then the charge is read, that is, measured over reading time R from time t₃ after holding time H (that is, Th in FIG. 13 of JP Publication Patent 7[1995]-5408) has passed. Wait time A₁ is produced between time t₁, when writing to pixel p_{j,1}, immediate before pixel P_{j,2}, it is completed, and time t₂, when writing to pixel P_{j,2} starts, in order to guarantee the holding time H of each pixel, even if the measurement of the next pixel P_{j,2} is such that the reading starts at time t₄ immediately after the reading of P_{j,1} is completed.

By means of the method in FIG. 14, the number of pixels of each pixel group becomes a maximum of N=H/R from the relationship between holding time H and reading time R. The total number of pixel groups is M.

It should be noted that hereafter, the i^{th} pixel of the j^{th} pixel group will be represented as P_{i,j} in the present Specification. The term pixel group refers to pixels that have been measured or tested, that is, inspected, as a group.

A₂ in FIG. 14 is the wait time, which is a fraction based on the relationship between holding time H and reading time R.

The total of the wait time A₁ in the entire display panel becomes, for instance, 26 seconds for the number of pixels in the display panel of Nonpatent Reference 1: 1280×1024=1,310,720, even if it is estimated that the difference between the writing time and the reading time, that is, the wait time, is 20 μs.

Therefore, an object of the present invention is to provide a high-speed testing method with which the writing time is shorter than the reading time for testing the holding properties of the holding capacitor of a TFT array.

Another object of the present invention is to provide a high-speed, high-accuracy testing method.

The above-mentioned object of the present invention is accomplished through the combination of the characteristics cited in the independent claims. Moreover, the subordinate claims give further useful specifics of the present invention.

### SUMMARY OF THE INVENTION

The first embodiment of the present invention is a method for measuring the holding properties of a TFT array of an active matrix that comprises multiple pixel circuits with holding capacitors, wherein each of the multiple pixel circuits comprises a holding capacitor, a switching transistor for connecting data lines with the holding capacitor, and a gate line for controlling the switching operation of the switching transistor, and these multiple pixel circuits consist of at least a first, second, third, and fourth pixel circuit, this measurement method being primarily characterized in comprising a step for measuring the charge of the holding capacitor of a first pixel circuit that has passed through a predetermined holding time after charging and then charging to the holding capacitor of a still uncharged third pixel circuit; a step for measuring the charge of the holding capacitor of a second pixel circuit that has passed through a predetermined holding time after charging and then charging to the holding capacitor of a still uncharged fourth pixel circuit; a step for measuring the charge of the holding capacitor of the third pixel circuit that has passed through the predetermined holding time after charging; and a step for measuring the charge of the holding capacitor of the fourth pixel circuit that has passed through the predetermined holding time after charging.

The present invention includes an embodiment further comprising a step for charging to the holding capacitor of the first and second pixel circuits prior to the step for measuring with the first pixel circuit and assigning the first and second pixel circuits to a first pixel group and the third and fourth pixel circuits to a second pixel group.

Moreover, the present invention includes an embodiment characterized in that by means of the step for assigning the pixel circuits to pixel groups, the first pixel circuit is assigned so that it is connected to a first data line and a first gate line and the second pixel circuit is assigned so that it is connected to the first data line and a second gate line next to the first gate line, and the third pixel circuit is assigned so that it is connected to a second data line next to the first data line and the first gate line and the fourth pixel circuit is assigned so that it is connected to the second data line and the second gate line.

The present invention also includes an embodiment characterized in that by means of the step for assigning the pixel circuits to pixel groups, the first pixel circuit is assigned so that it is connected to the first data line and the first gate line; the second pixel circuit is assigned so that it is connected to the second data line next to the first data line and the second gate line next to the first gate line; the third pixel group is assigned so that it is connected to the first data line and a third gate line next to the first gate line and on the side opposite the second gate line; and the fourth pixel circuit is assigned so that it is connected to the second data line and the first gate line, as well as the embodiment characterized in that in this case, when any of the first, second, third, and fourth pixel circuits is being charged, the other pixel circuits connected to the gate lines connected to the pixel circuits being charged are not charged or measured until the charge of the pixel circuit being charged is measured, and when any of the first, second, third, and fourth pixel circuits is being measured, the other pixel circuits connected to the data lines connected to the pixel circuits being measured are not charged.

The present invention further includes the embodiment characterized in that by means of the step for assigning the pixel circuits to pixel groups, the first pixel circuit is assigned so that it is connected to the first data line and the first gate line; the second pixel circuit is assigned so that it is connected to the second data line next to the first data line and the second gate line next to the first gate line; the third pixel circuit is assigned so that it is connected to a third data line next to the first data line and on the side opposite the second data line; and the fourth pixel circuit is assigned so that it is connected to the first data line and the second gate line, as well as the embodiment wherein in this case, when any of the first, second, third, and fourth pixel circuits is being charged, the other pixel circuits connected to the gate lines connected to the pixel circuits being charged are not charged or measured until the charge of the pixel circuit being charged is measured, and when any of the first, second, third, and fourth pixel circuits is being measured, the other pixel circuits connected to the data lines connected to the pixel circuits being measured are not charged.

The present invention includes the embodiment of a method for measuring the holding properties of a TFT array of an active matrix that comprises multiple pixel circuits with holding capacitors, wherein each of the multiple pixel circuits comprises a holding capacitor, a switching transistor for connecting data lines with the holding capacitor, and a gate line for controlling the switching operation of the switching transistor, and these multiple pixel circuits consist of at least a first, second, third and fourth pixel circuit, this measurement method being characterized in that it comprises a step for charging each pixel circuit of the first pixel group; a step for performing for each pixel circuit of both pixel groups a measurement of the charge from one of the pixel circuits of the first pixel group and charging of one of the pixel circuits of the second pixel group; and a step for measuring the charge from each pixel circuit of the second pixel group, and in that by means of the assignment step, each of the circuits of the first and second pixel groups is assigned so that the gate lines and data lines are different and comprises a pixel circuit connected to a data line or a gate line connected to a pixel circuit whose charge has been measured, and a different pixel circuit connected to this data line or gate line then charges an uncharged pixel circuit.

The present invention also includes the embodiment characterized in that the TFT array in each of the above-mentioned embodiments has a two-way shift register.

### BRIEF DESCRIPTION OF THE DRAWINGS

FIG. 1 is a block diagram of the testing circuit of the present invention.

FIG. 2 is a block diagram showing the circuit of the H shift register 140 in FIG. 1.

FIG. 3 is a block diagram showing the circuit of V shift register 142 of FIG. 1.

FIG. 4 is a block diagram describing the pixel circuit under test of the present invention.

FIG. 5 is the timing chart that describes the test by the present invention.

FIG. 6 is a schematic drawing describing the sequence of the test shown in FIG. 5.

FIG. 7 is a flow chart explaining one example of the present invention.

FIG. 8 is a flow chart describing in detail a part of the flow chart in FIG. 7.

FIG. 9 is a schematic drawing showing a working example of the method of selecting pixel groups of the present invention.

FIG. 10 is a schematic drawing showing a different working example of the method of selecting pixel groups of the present invention.

FIG. 11 is a schematic drawing showing yet another example of the method of selecting pixel groups of the present invention.

FIG. 12 is a circuit diagram that explains the effect of the method in FIGS. 10 and 11.

FIG. 13 is a block diagram of the test device that operates by the test method of the prior art.

FIG. 14 is a timing chart that describes the testing method based on the prior art.

### DETAILED DESCRIPTION OF THE PREFERRED EMBODIMENT

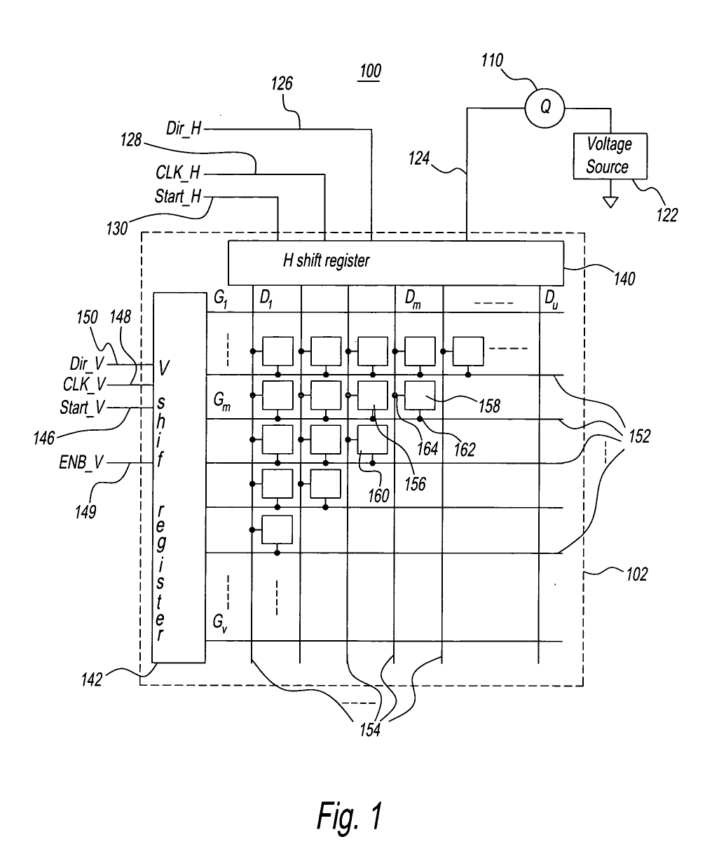

Preferred embodiments of the present invention will be described while referring to FIGS. 1 through 12.

FIG. 1 shows a block diagram of a measuring device 100 for a TFT array of the present invention.

Each pixel circuit of the TFT array is simply called a “pixel” in the following description.

A TFT array 102 comprises multiple pixels (keyed as 156, 158, 160, and so forth), and the voltage specified by the data line is written to a predetermined pixel by selecting a gate line 152 with a V shift register 142 or selecting a data line 154 with an H shift register 140. H shift register 140 and V shift register 142 each comprise a CLK_H (128), a CLK_V (148), pulse input terminals Start_H (130), Start_V (146), shift direction terminals Dir_H (126) and Dir_V (150), and an enable terminal ENB_V (149).

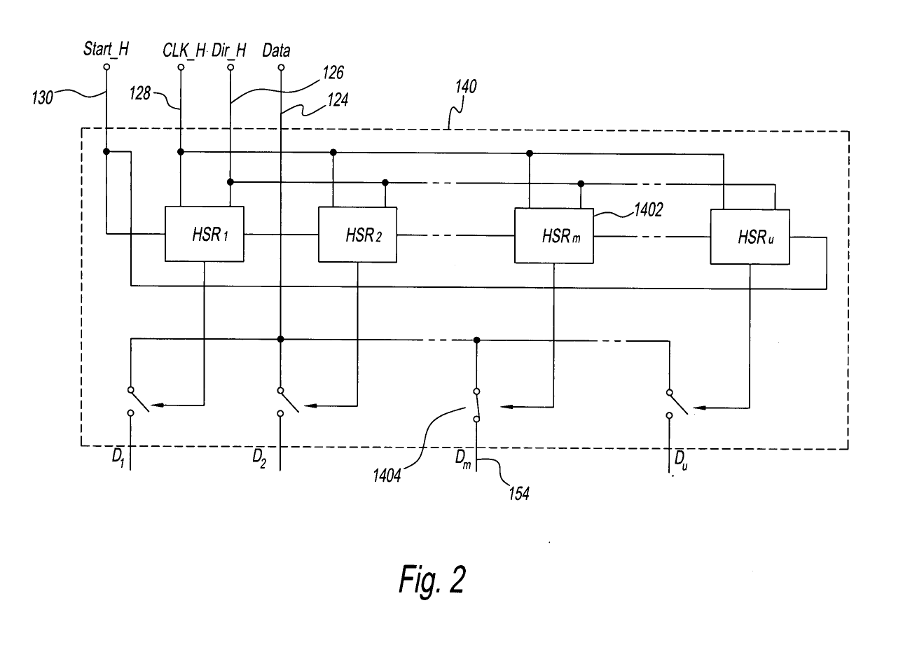

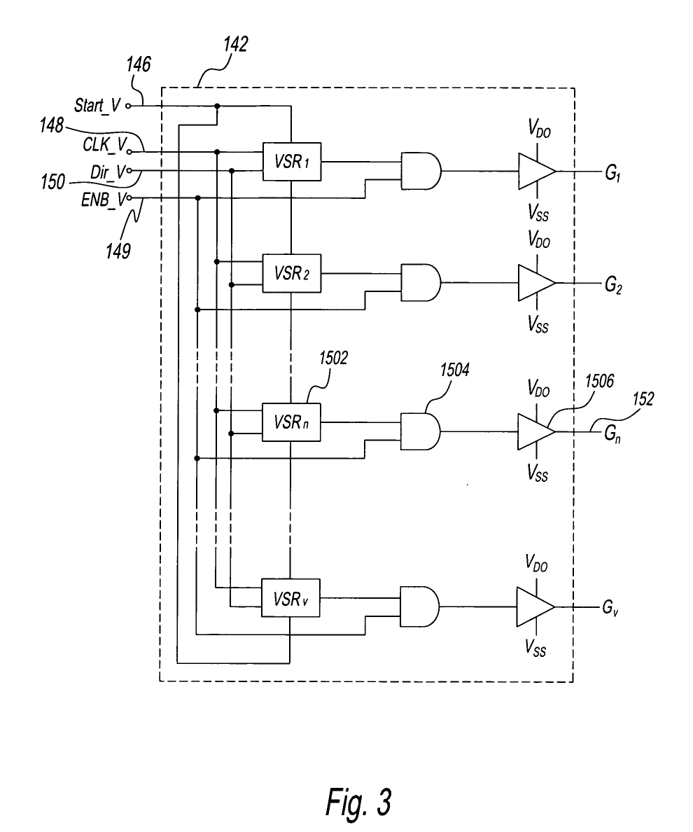

Each shift register shifts signals given to the pulse input terminal in accordance with clock signals given to the clock signal terminal in the direction specified by signals given to the shift direction terminal. Examples of H shift register 140 and V shift register 142 will now be described while referring to the schematic representations shown in FIGS. 2 and 3, respectively.

Referring to FIG. 2, H shift register 140 comprises U number of shift registers HSR₁ through HSR_{U}, including HSRₘ 1402. H shift register 140 shifts logic high signals given to pulse input terminal Start_H 130 in the direction prescribed by Dir_H terminal 126 by the number of clock signals given to clock terminal CLK_H (128); the relay connected with the shift register (HSRₘ 1402 in this case) that stores logic high signals is closed; and as a result, the signals given to a Data terminal 124 are output to a data line 154 (Dₘ in the figure). Thus, the data lines that have not been selected are in an open state.

There are also H shift registers that have enable terminals, and in this case, a prescribed relay 1404 is closed only when the enable terminal is at logic high.

Next, referring to FIG. 3, V shift register 142 comprises V number of shift registers VSR₁ through VSR_{V}, including VSRₙ 1502. V shift register 142 shifts logic high signals given to pulse input terminal Start_V 146 in the direction prescribed by Dir_V terminal 150 by the number of clock signals given to clock terminal CLK_V (148). In this example, logic high signals are output from shift register VSRₙ 1502; logic high signals are output from an AND circuit 1504 connected to the output of VSRₙ 1502 only when logic high signals are given to enable terminal ENB_V (149); and these signals are buffer-amplified by a buffer 1506 and ON voltage Vₒₙ is output to a gate line Gn 152.

On the other hand, the shift register that was not selected outputs logic low signals; these are buffer-amplified by a buffer; and as a result, OFF voltage V_{off} is output to a gate line that was not selected.

It should be noted that another variation of the V shift register does not comprise an enable terminal such as ENB_V (149), and in this case, there is no AND circuit 1504, and ON voltage Vₒₙ is output to the gate line simply by selecting the shift register.

Returning to FIG. 1, a variable voltage source 122 for applying voltage to the selected data line and a charge meter 110 for measuring the charge that has moved through the data line are connected in series to a power source terminal 124 of H shift register 140.

Each pixel, for instance, pixel 158, of TFT array 102 is connected with a predetermined gate line (Gₙ in the case of pixel 158) by a line 162 and similarly, a predetermined data line (Dₘ in the case of pixel 158) by a line 164.

Unless otherwise specified, the phrase “written (writing)” in the pixel or holding capacitor of the present Specification means that the holding capacitor of that pixel is “charged,” and the term “read” from the pixel or holding capacitor means “charge is discharged and this charge is measured” from the holding capacitor of that pixel.

TFT array 102 used in the tests by the present invention is a liquid crystal or EL display panel. The present invention can be used to test display panels before forming the liquid crystals or EL elements. The present invention can also be used for display panels after the formation of liquid crystals or EL elements.

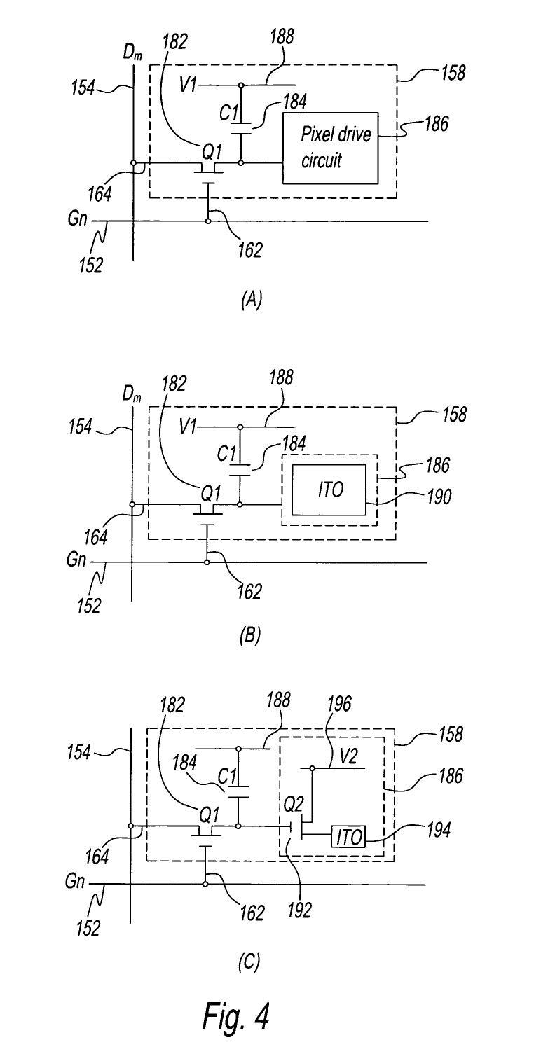

As shown in FIG. 4(A), each pixel, whether it is a liquid crystal or EL display element, comprises a pixel selection transistor Q1 (182) wherein a gate and source are connected to gate line Gₙ (152) and a data line Dₘ (154), respectively; a holding capacitor C1 (184), which is connected to the drain terminal of the transistor and stores the output voltage of transistor Q1 between the transistor and a common power source V1 (188); and a pixel drive circuit 186 connected to the same drain.

As shown in FIG. 4(B), the pixel drive circuit of a liquid crystal display panel comprises only an ITO electrode terminal (190) for forming the liquid crystal.

As shown in FIG. 4(C), pixel drive circuit 186 for an EL display panel comprises a transistor Q2 (192) for current driving, an ITO electrode terminal 194, and an EL driving power source V2 (196). An EL can be formed on ITO electrode terminal 194 and connected to any signal line in advance. It should be noted that the measurement of the holding capacitor is made without relation to whether the EL element has been formed on ITO electrode terminal 194 or not.

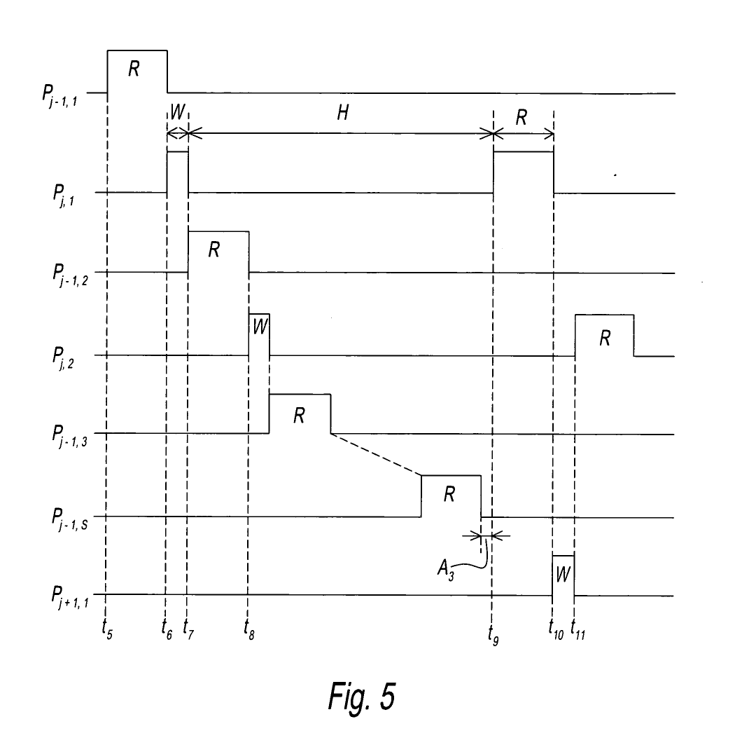

Next, the measurement algorithm of the present invention will be described using FIG. 5. By means of the present Specification, the i^{th} pixel of the j^{th} pixel group is called P_{j,i}, the gate line of this pixel is called G_{j,i}, and the data line is called D_{j,i}.

First, writing is started at time t₆ with emphasis placed on the holding capacitor of the 1st pixel P_{j,1} of the j^{th} pixel group in the present invention. Next, reading of the second pixel P_{j-1,2} of the j−1 pixel group starts at time t₇ after writing time W has passed. Writing has already been performed at this pixel P_{j-1,2} and holding time H has passed. Next, reading of P_{j-1,2} is completed at time t₈ after reading time R has passed and the writing of second pixel P_{j,2} of the j^{th} pixel group starts.

As shown in FIG. 5, the reading of the first pixel P_{j-1,1}, of the j-1 pixel group starts at time t₅ before the writing of pixel P_{j,1}.

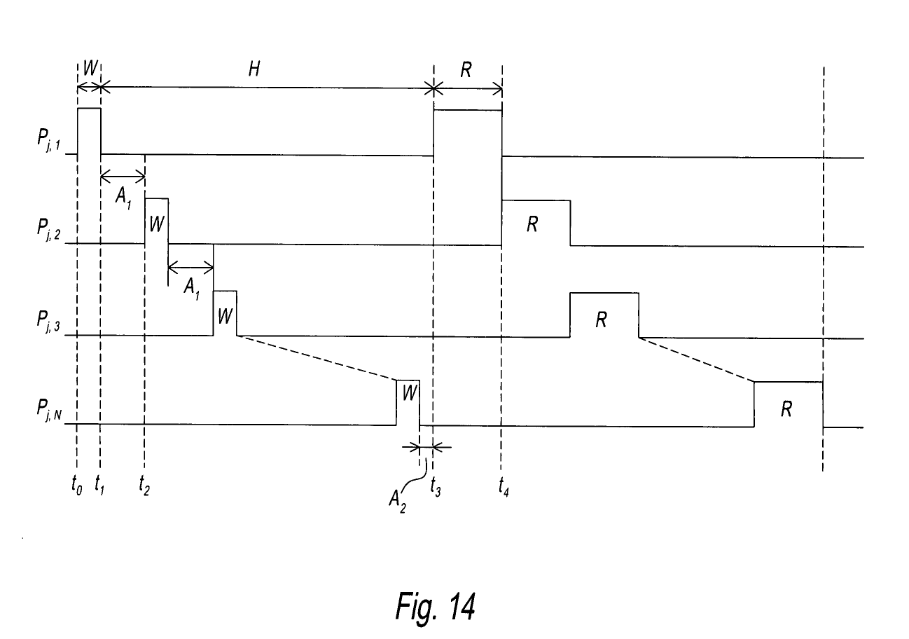

Thus, it is possible to alternate between reading a written pixel from the group directly before and writing a pixel group that is written starting at this moment. Therefore, the wait time A₁ shown in FIG. 14 is not produced. Thereafter, all the pixels of two groups are read and written; the reading of the first pixel P_{j,1} of the j^{th} pixel group, which has already been written and passed through holding time H, begins at time t₉ after wait time A₃, which is a fraction produced by a relationship with the holding time; and the writing of the first pixel P_{j+1,1} of the next j+1 pixel group starts at time t₁₀ after reading time R has passed. The number of pixels in one pixel group S is represented here by S=H/(W+R), and the total number of pixel groups is represented by T.

A shift register is used to select the gate line and the data line between each pixel; therefore, once the writing of a certain pixel has been completed, the test device is controlled such that Dir_H 126 and Dir_V 150 select the optimal direction of movement to the position of the next pixel and the shift operations over one or more clocks necessary for movement to the desired pixel is performed (not illustrated in FIG. 1). Consequently, a measurement timing design that takes the time margin of this shift operation is necessary. However, the shift register operating clock is sufficiently short when compared to the writing time and reading time. Therefore, the time it takes to select the pixels on the entire display panel is also sufficiently short and there is little effect on the entire testing time.

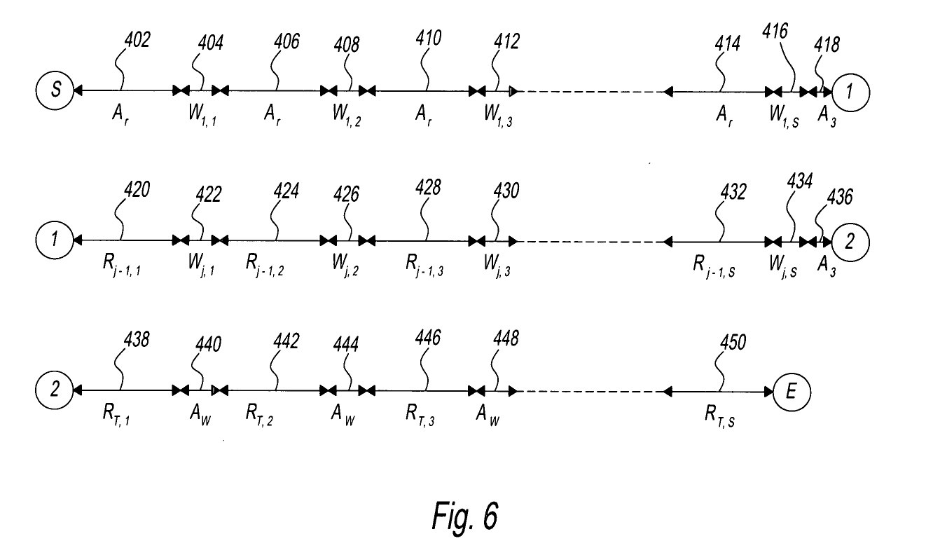

The algorithm introduced with FIG. 5 will now be described in more specific terms using FIG. 6. FIG. 6 is a schematic representation of the writing time/reading time/wait time from the start of the test (node S) to the end of the test (node E), and length of the x-axis is proportional to the length of time. The distance between node S and node 1 indicates the period when writing is performed on the first pixel group. In this case, there are no pixels that are read together; therefore, wait times Aᵣ (402, 406, 410, 414) corresponding to reading time are inserted between each writing. That is, a cycle of waiting for period Aᵣ (402); writing W_{1,1} (404) on the first pixel of the first group; waiting for period Aᵣ (406); and writing W_{1,2} (408) on the second pixel of the first pixel group is repeated, followed by writing W_{1,S} (416) on the last pixel of the first pixel group and, furthermore, waiting for fractional wait time A₃ (418).

Next, the distance between node 1 and node 2 is the period of alternation between the reading of each pixel of the pixel group that has already passed through holding time H and the writing on each pixel of a new pixel group. That is, a cycle of reading R_{j-1,1} (420) of the first pixel of the j−1 pixel group, which has already been written and passed through a holding time; writing W_{j,l} (422) on the first pixel of the j^{th} pixel group; reading R_{j-1,2} (424) on the second pixel of the j−1 pixel group; and writing on the second pixel of the j^{th} pixel group is repeated, R_{j-1,S} (432) and W_{j,s} (434) are performed for the last pixel of both groups, and fractional wait time A₃ (436) is applied, to reach node 2.

There are no pixels that will be newly written between the last node 2 and node E; therefore, wait time A_{w} (440, 444, 448) is instead inserted corresponding to the writing time. That is, a cycle of reading R_{T,1} (438) of the first pixel of the T pixel group, which is the last pixel group; waiting for A_{w} (440); reading R_{T,2} (442) of the second pixel of the T pixel group; and waiting for A_{W} (444) is repeated, followed by reading R_{T,S} (450) of the final pixel to reach node E and complete the test. There are cases where the number of pixels in the final pixel group is less than S number based on the relationship with the number of pixels of the display panel, and the algorithm can be corrected as needed in this case.

Moreover, other modifications can be added, such as setting up a pixel group with less than S number of pixels or setting a wait time in the writing or reading cycle of pixel groups not having S number of pixels even before node 2 is reached based on the algorithm shown in FIG. 6.

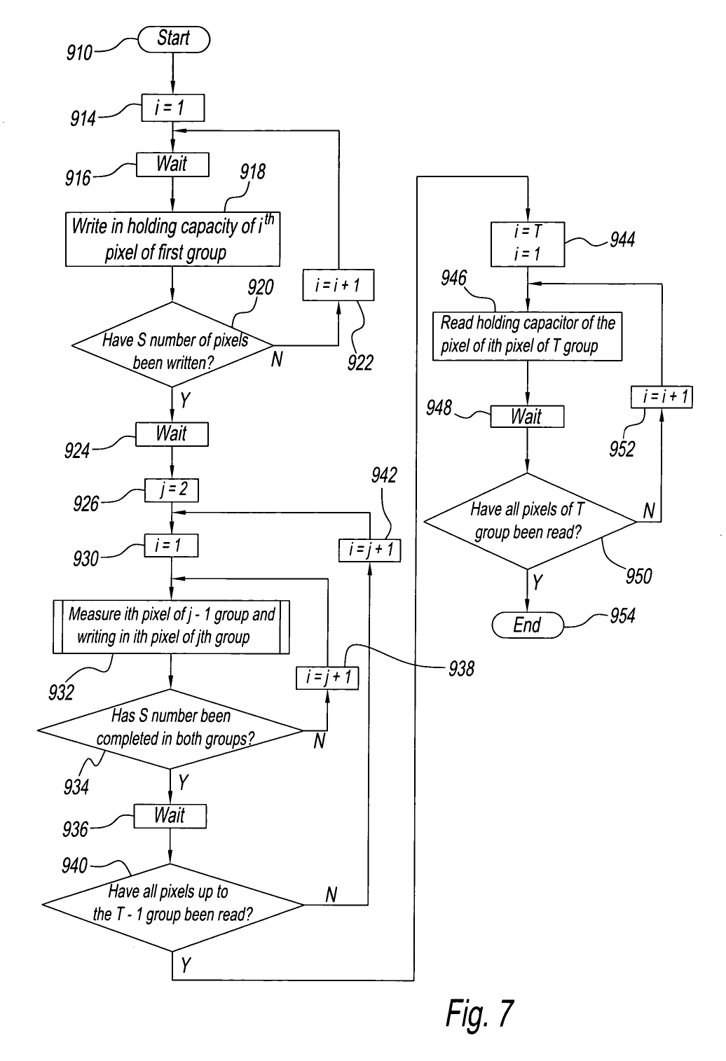

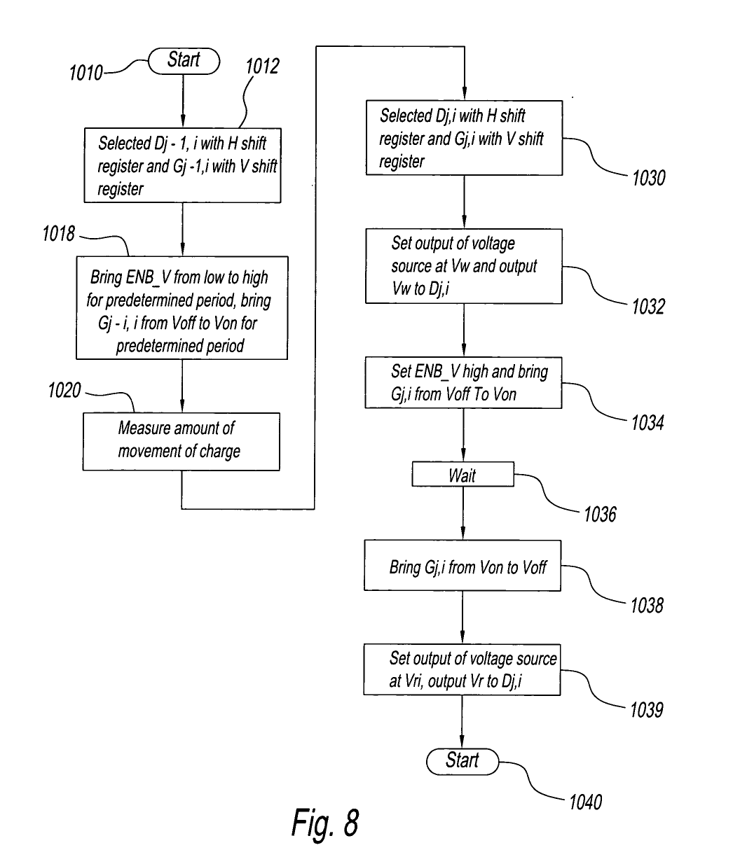

Next, the algorithm shown in FIG. 6 will be described in further detail using the flow chart in FIGS. 7 and 8. In FIG. 7, the program starts at Step 910 at variable i showing the pixel number in the pixel group is initialized at 1 in step 914. Then the program waits for waiting time Aᵣ corresponding to the reading time of the pixel at step 916, writes in the holding capacitor of the i^{th} pixel of the first pixel group at step 918, evaluates whether or not all S number of pixels in the first pixel group have been written at step 920, and if they have not, obtains the increment of the variable i at step 922, and repeats itself from step 918. Moreover, the program waits for waiting time A₃ at step 924 if S number of pixels have been written. The system moves from node S to node 1 in FIG. 6 by the above-mentioned procedure.

Next, variable j showing the pixel group number to be written is initialized at 2 in step 926. The j^{th} pixel group is selected for writing and the j−1 pixel group is selected for reading. Variable i is initialized at 1 in step 930, the i^{th} pixel of the j−1 pixel group is read at step 932, and the i^{th} pixel of the j^{th} pixel group is written. The program evaluates whether or not S number of pixels of both groups have been written at step 934 and if the result is NO, finds the increment for variable i at step 938 and repeats itself from step 932. If the result is YES, the program waits for waiting time A₃ in step 936 and evaluates whether or not variable j is T−1, that is, whether or not all of the pixels in the T−1 group have been read, in step 940. If the answer is NO, the program finds the increment for variable j at step 942 and repeats itself from step 928. The program moves from node 1 to node 2 in FIG. 6 by the above-mentioned procedure.

If the result of step 940 is YES, the programs sets variable j to T and initializes variable i at 1 at step 944, measures the i^{th} pixel of the T pixel group at step 946, and waits for time A_{w} corresponding to writing at step 948. The program evaluates whether or not all pixels of the T pixel group have been measured at step 950 and if the result is NO, the program finds the increment of variable i at step 952 and repeats step 946. If the result is YES, the program ends at step 954.

Next, step 932 is described with a more detailed flow chart using FIG. 8. The details of steps 918 and 946 have been omitted because they have been replaced by wait time in FIG. 8.

First, the output voltage of variable voltage source 122 can be initially output as writing voltage Vw and reading voltage Vr. Precautions should be taken to initially set the voltage to reading voltage Vr. Moreover, in one example, writing voltage Vw is 5 V and reading voltage Vr is 0 V. The routine is started at step 1010 in FIG. 8, and then first data line D_{j-1,i} connected to pixel P_{j-1,i} is selected by H shift register 140, and gate line G_{j-1,i} connected to pixel P_{j-1,i} is selected by V shift register 142 at step 1012. As a result, charge meter 110 and variable voltage source 122 are connected to pixel P_{j-1,i} through H shift register 140.

Next, in step 1018, enable terminal ENB_V is brought to logic high for a predetermined period and gate line G_{j-1,i} is set for the predetermined period from OFF voltage Voff to On voltage Von and then returned to OFF voltage Voff. As a result, pixel selecting transistor Q1 (182 in FIG. 4) of pixel P_{j-1,i} is brought to an ON state for a predetermined period as the discharge time of the holding capacitor and a charge passes through transistor Q1 (182) between holding capacitor C1 (184 in FIG. 4) and the charge meter (110 in FIG. 1) in balance with the potential difference of data line D_{j-1,i}.

Next, the charge that has moved through data line D_{j-1,i} is measured by charge meter 110 in step 1020.

Next, data line D_{j,i} connected to pixel P_{j,i} is selected by H shift register 140, and gate line G_{j,i} connected to pixel P_{j,i} is selected by V shift register 142 in step 1030. Then the output voltage of variable voltage source 122 is set at writing voltage Vw and the output of data line D_{j,i} connected to pixel P_{j,i} becomes writing voltage Vw at step 1032. Enable terminal ENB_V is brought to logic high at step 1034, and gate line G_{j,i} is set from Voff to Von. Next, a predetermined waiting period is applied as the charge time to the holding capacitor in step 1036. Enable terminal ENB_V is brought to logic low in step 1038 and the output of gate line G_{j,i} is brought from ON voltage Von to OFF voltage Voff. The output voltage of variable voltage source 122 is set at reading voltage Vr and the output of data line D_{j,i} becomes reading voltage Vr in step 1039. Finally, the routine is completed at step 1040.

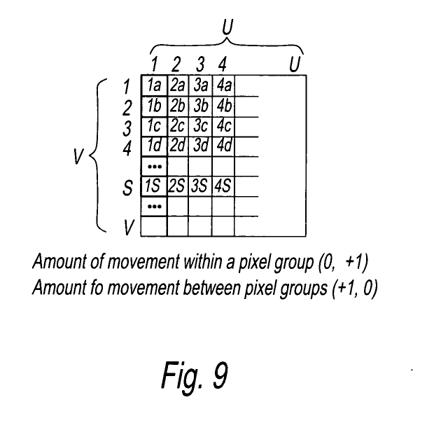

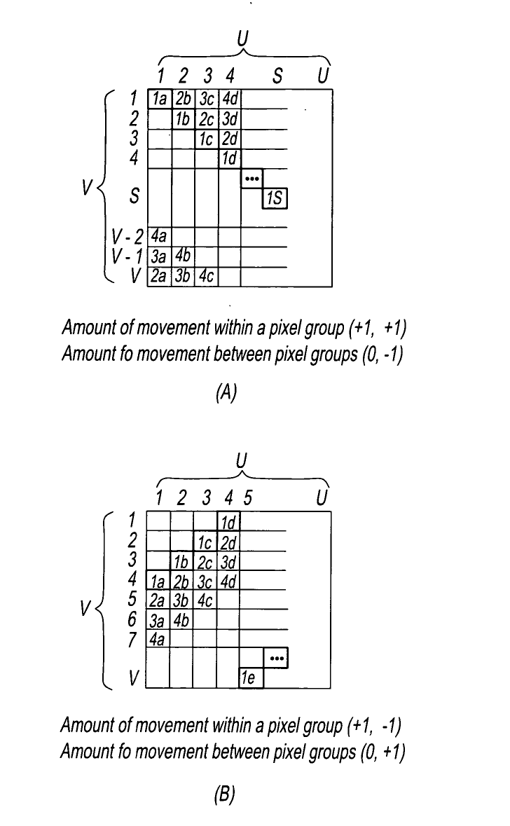

The method for selecting the pixels to be read and written, that is, the method for identifying the pixel group (pixel sequence) used in the measurement algorithm of the present invention will be described with FIGS. 9 through 12.

In order to facilitate the description, the position of each pixel is represented using X, Y coordinates with the top left corner of the display panel being 1. For instance, pixel (3,1) in FIG. 9 is represented as the pixel written, labeled “3a.” Furthermore, the number in the first position on the label is the pixel group number and the letter in the second position on the label is the order of the pixel in that pixel group. In this example, pixel (3,1) in FIG. 9 is labeled “3a,” and this represents the first pixel of the third group. Each pixel of the third pixel group in FIG. 9 is assigned in order from pixel 3a (3,1) to pixel 3S (3,S). Moreover, the size of the display panel is represented by U×V, with the number of data lines being U and the number of gate lines being V.

FIG. 9 is one example of an assignment method whereby pixels are easily and quickly selected for writing and reading. Pixels groups are assigned for all of the pixels on the display panel by the procedure of starting with pixel (1,1) of the first pixel group, selecting S number of pixels from the top to the bottom, moving to the next group of pixels one column to the right, and starting with pixel (2,1) and selecting S number of pixels from the top to the bottom. When the method is described at step 932 in FIG. 7, the gate line is the same gate line when the routine reads at the i^{th} pixel of the j−1 pixel group and then reads the i^{th} pixel of the next j^{th} pixel group; therefore, it is possible to simply select an adjacent pixel group by data line. The algorithm is simple and takes less time to move to through the pixels under test.

In another version of this assignment method, it is possible to select the next column to the left of the current pixel group as the next pixel group. Moreover, pixel groups can be assigned by regarding the top and bottom and right and left ends of the display panel as being cyclically connected.

By means of yet another version of this method, the pixels of each group are selected from the bottom to the top rather than from the top to bottom. The position of the next pixel group depends on how the pixels in the previous pixel group are selected. When the pixels are selected from the bottom to the top, the next pixel group can be the pixel group just to the right or the left of the previous pixel group.

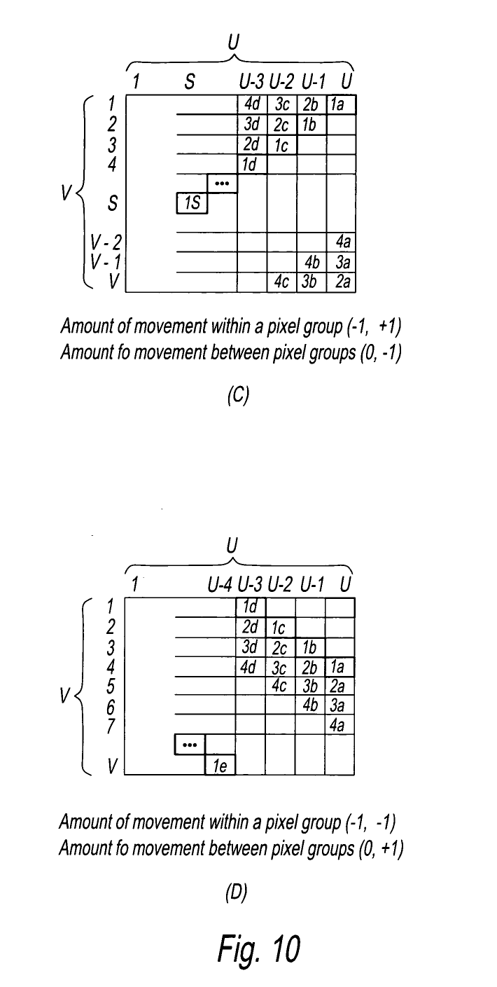

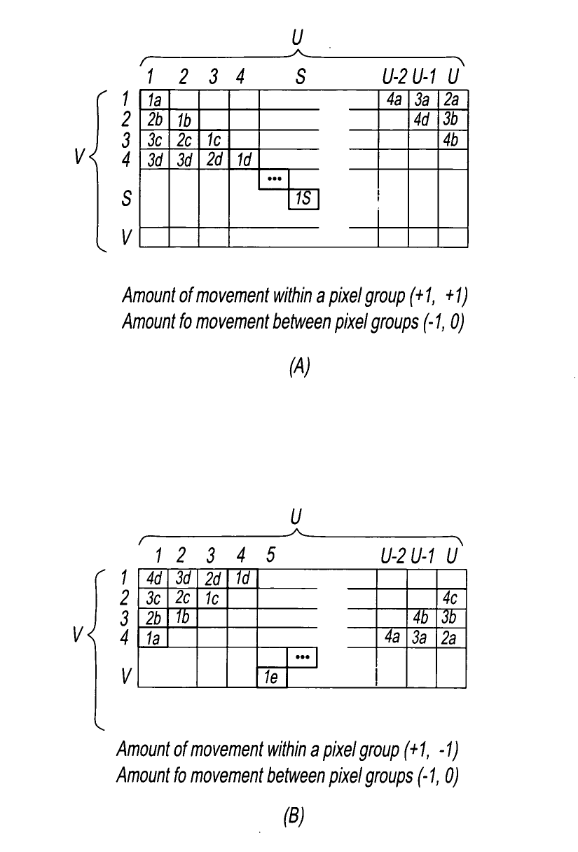

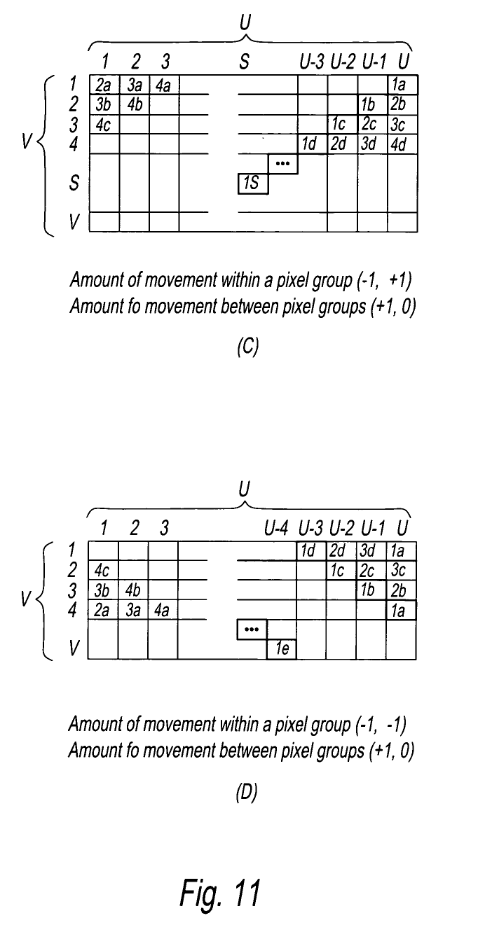

FIGS. 10 and 11 are examples of using the assignment method to realize precise measurement.

FIG. 10(A) is a schematic representation of the method of selecting the pixel sequence of each pixel group using a system whereby a shift of (+1, +1) is executed in the X and Y directions as the amount of movement of pixel selection within a group, and a shift of (0, −1) is executed as the amount of movement between pixel groups. Only the first four pixels of a total of S number of pixels are shown as the pixels of the first pixel group. Pixels are selected moving to the right and down as 1a through 1d with pixel (1,1) serving as the starting point. The second pixel group is selected as shown by 2a through 2d with pixel (1, V) as the starting point. It should be noted that the coordinates from the top to bottom and left to right of the display panel are selected as cyclically connected.

Similarly, another example of the present invention is the selection system shown in FIG. 10(B) where the amount of movement within a pixel group is (+1, −1) moving to the right and up and the amount of movement between pixel groups is (0, +1), with the starting pixel moving down, one pixel at a time.

Yet another example of the present invention is the selection system shown in FIG. 10(C), whereby the amount of movement within a pixel group is (−1, +1) moving to the left and down, and the amount of movement between pixel groups is (0, −1), with the starting pixel moving up, one pixel at a time.

Still another example of the present invention is the selection system shown in FIG. 10(D), whereby the amount of movement within a pixel group is (−1, −1) moving to the left and up, and the amount of movement between pixel groups is (0, +1), with the starting pixel moving down, one pixel at a time.

Table 1 below shows the amount of movement of the H shift register and the V shift register when a pixel is selected by the four systems shown in FIG. 10. The number of the signal line of the data line is represented by D and the number of the gate line is represented by G. Pixels are selected as follows. The direction of the shift of the respective shift register is selected at the shift direction input terminals (Dir_H, Dir_V) from the amounts listed here; the necessary clock CLK_H or CLK_V is input; and, when a cyclic operation is to be started, a pulse input is sent to terminals Start_H and Start_V in order to start the shift register. It is clear from the table that the four systems represented in Table 10 are systems that help to minimize the amount of movement between pixels and curtail test time.

TABLE 1

| Amount of | | | | |
|---|---|---|---|---|
| Movement | +1, +1 | +1, −1 | −1, +1 | −1, −1 |
| 1a→1b | D = D + 1 | D = D + 1 | D = D − 1 | D = D − 1 |
| | G = G + 1 | G = G − 1 | G = G + 1 | G = G − 1 |
| 1S→2a | D = D − | D = D − | D = D + | D = D + |
| | S + 1 | S + 1 | S − 1 | S − 1 |
| | G = G − | G = G − | G = G + | G = G + |
| | S − 1 | S + 1 | S − 1 | S − 1 |
| 2a→1b | D = D | D = D | D = D | D = D |
| | G = G + 1 | G = G − 1 | G = G − 1 | G = G + 1 |
| 1a→2b | D = D + 1 | D = D + 1 | D = D − 1 | D = D − 1 |
| | G = G | G = G | G = G | G = G |

FIG. 11 shows a different pixel group selection method from the four methods in FIG. 10. FIG. 11(A) shows a selection system whereby the amount of movement for selecting pixels within a pixel group is (+1, +1), to the right and down as in FIG. 10(A), but the amount of movement between pixel groups is (−1, 0), and the starting pixel moves to the left, one pixel at a time. It should be noted that the top and bottom and right and left coordinates of the display panel are selected as coordinates that are cyclically connected.

Similarly, FIG. 11(B) shows a selection system as another example of the present invention whereby the amount of movement within a pixel group is to the right and up by (+1, −1), and the amount of movement between pixel groups is (−1, 0), with the starting pixel moving to the left, one pixel at a time.

FIG. 11(C) shows yet another selection system as an example of the present invention whereby the amount of movement within a pixel group is to the left and down by (−1, +1), and the amount of movement between pixel groups is (+1, 0), with the starting pixel moving to the right, one pixel at a time.

FIG. 11(D) shows yet another selection system as an example of the present invention whereby the amount of movement within a pixel group is to the left and up by (−1, −1), and the amount of movement between pixel groups is (+1, 0), with the starting pixel moving to the right one pixel at a time.

The amount of movement of the H shift register and the amount of movement of the V shift register by the four systems in FIG. 11 can be discussed as in Table 1 for FIG. 10, and it is clear that these methods help to curtail test time and minimize the amount of movement between pixels.

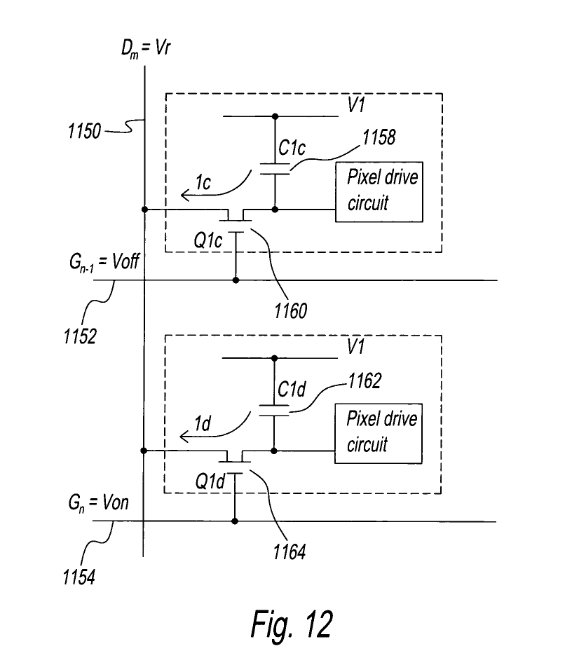

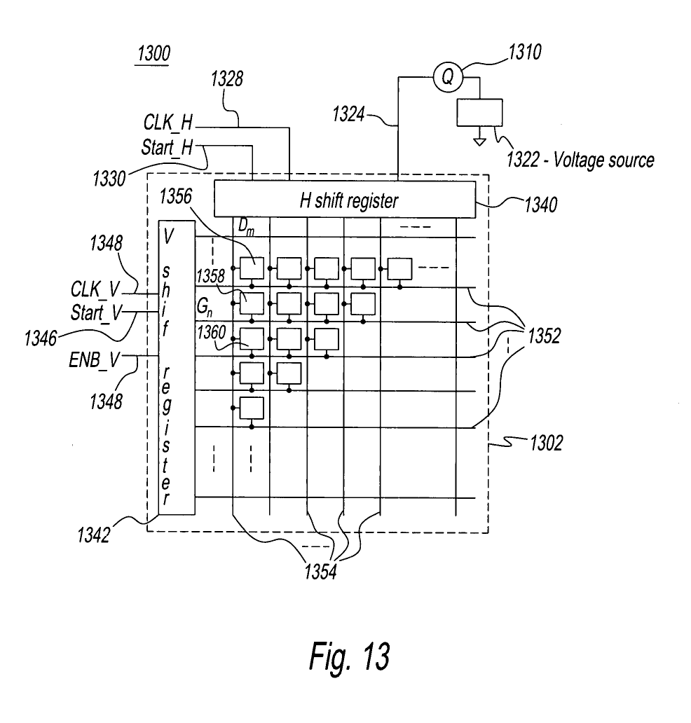

The reason why high precision measurement can be realized by the method in FIGS. 10 and 11 will be discussed. FIG. 12 shows pixel circuits with different gate lines, but a shared data line. The case will be considered where the charge of holding capacitor C1d of the pixel at the bottom selected by gate line Gₙ 1154 and data line Dₘ 1150 is measured. Reading voltage Vr is applied to data line Dₘ, ON voltage Von is applied to gate line Gₙ 1154, and as a result, the charge stored in holding capacitor C1d is discharged through transistor Q1d by voltage Vr of data line Dₘ.

Taking into consideration pixel selecting transistor Q1c for pixels with a common data line but different gate lines, pixel selecting transistor Q1c is OFF because gate line Gₙ₋₁ (1152) is Voff, but leakage current flows as a result of this OFF resistance. In particular, when holding capacitor C1c is charged and waiting for the holding time to pass, the potential difference between the source and drain of pixel selecting transistor Q1c becomes Vw−Vr and is very large. Consequently, leakage current also increases. If holding capacitor C1c has been measured, the potential difference between the source and drain of pixel selecting transistor Q1c is 0; therefore, leakage current is extremely small. That is, the total of the leakage current flowing to data line Dₘ increases with an increase in the number of pixels having a common data line but different gate lines that are charged and waiting for the holding time to pass. Consequently, measurements of the amount of movement during charge change with the order of the measurements inside a pixel group. It should be noted that this is true for all of multiple pixels with a common data line and without relation to adjacency of pixels.

Pixels are selected as a sequence by pixel groups in the working examples in FIGS. 10 and 11 in order to solve the above-mentioned problem. First, there must be compliance with the following two points when selecting pixels:

A1) A gate line of a charge pixel is not selected until the holding time has passed.

A2) Other pixels connected to a data line of the pixels to be measured is not charged.

In other words, there are the following selection rules:

B1) Each pixel is selected such that the gate lines and the data lines are different for any pixel within a pixel group.

B2) Once a certain pixel has been measured, a pixel that shares a data line or gate line with that pixel can be charged. However, the pixel to be charged does not share a data line or gate line with any of the other pixels when a charge is being held.

Referring to FIGS. 10 and 11, it is clear that above-mentioned rules B1 and B2 are satisfied by both of the examples in the figures and that there are none of the inconveniences such as in FIG. 12.

The holding properties of the holding capacitor of the active array matrix of the present invention were described with different examples, but these were disclosed for the purpose of illustrating the present invention and it should be pointed out that the present invention is in no way limited to these examples. Various modifications easily understood by persons skilled in the art are possible. For instance, a system can also be considered where the amount of movement of a pixel within a group is larger than 1, and the starting pixel can be set at a place other than the edge of the display panel.

The present invention was described for display panels wherein the H shift register and the V shift register can shift in both directions, but taking into consideration the sufficient pixel selection time margin, the present invention can also be used for display panels with shift registers wherein either or both of the H shift register and V shift register shifts in one direction only.

Furthermore, defects in the properties of the holding capacitor of the present invention can be fed back to the previous step in the TFT array production process and used to improve process quality.

What is claimed is:

1. A method for measuring the holding properties of a TFT array of an active matrix display panel that comprises multiple pixel circuits with holding capacitors wherein each of the multiple pixel circuits comprises a holding capacitor, a switching transistor for connecting data lines with the holding capacitor, and a gate line for controlling the switching operation of the switching transistor, and these multiple pixel circuits consist of at least a first, second, third, and fourth pixel circuit, said method comprising:
measuring the charge of the holding capacitor of a first pixel circuit that has passed through a predetermined holding time after charging and then charging to the holding capacitor of a still uncharged third pixel circuit;
measuring the charge of the holding capacitor of a second pixel circuit that has passed through a predetermined holding time after charging and then charging to the holding capacitor of a still uncharged fourth pixel circuit;
measuring the charge of the holding capacitor of the third pixel circuit that has passed through the predetermined holding time after charging; and
measuring the charge of the holding capacitor of the fourth pixel circuit that has passed through the predetermined holding time after charging.

2. The measurement method according to claim 1, further comprising:
charging to the holding capacitor of the first and second pixel circuits prior to measuring with the first pixel circuit; and
assigning the first and second pixel circuits to a first pixel group and the third and fourth pixel circuits to a second pixel group.

3. The measurement method according to claim 2, wherein the first pixel circuit is assigned so that it is connected to a first data line and a first gate line and the second pixel circuit is assigned so that it is connected to the first data line and a second gate line next to the first gate line, the third pixel circuit is assigned so that it is connected to a second data line next to the first data line and the first gate line, and the fourth pixel circuit is assigned so that it is connected to the second data line and the second gate line.

4. The measurement method according to claim 2, wherein the first pixel circuit is assigned so that it is connected to a first data line and a first gate line; the second pixel circuit is assigned so that it is connected to a second data line next to the first data line and a second gate line next to the first gate line; the third pixel group is assigned so that it is connected to the first data line and a third gate line next to the first gate line, and on the side opposite the second gate line; and the fourth pixel circuit is assigned so that it is connected to the second data line and the first gate line.

5. The measurement method according to in claim 2, wherein the first pixel circuit is assigned so that it is connected to a first data line and a first gate line; the second pixel circuit is assigned so that it is connected to a second data line next to the first data line and a second gate line next to the first gate line; the third pixel circuit is assigned so that it is connected to a third data line next to the first data line and on the side opposite the second data line; and the fourth pixel circuit is assigned so that it is connected to the first data line and the second gate line.

6. The measurement method according to claim 1, when any of the first, second, third, and fourth pixel circuits is being charged, the other pixel circuits connected to the gate lines connected to the pixel circuits being charged are not charged or measured until the charge of the pixel circuit being charged is measured, and
when any of the first, second, third, and fourth pixel circuits is being measured, the other pixel circuits connected to the data lines connected to the pixel circuits being measured are not charged.

7. The measurement method according to claim 2, when any of the first, second, third, and fourth pixel circuits is being charged, the other pixel circuits connected to the gate lines connected to the pixel circuits being charged are not charged or measured until the charge of the pixel circuit being charged is measured, and
when any of the first, second, third, and fourth pixel circuits is being measured, the other pixel circuits connected to the data lines connected to the pixel circuits being measured are not charged.

8. The measurement method according to claim 4, when any of the first, second, third, and fourth pixel circuits is being charged, the other pixel circuits connected to the gate lines connected to the pixel circuits being charged are not charged or measured until the charge of the pixel circuit being charged is measured, and
when any of the first, second, third, and fourth pixel circuits is being measured, the other pixel circuits connected to the data lines connected to the pixel circuits being measured are not charged.

9. The measurement method according to claim 5, when any of the first, second, third, and fourth pixel circuits is being charged, the other pixel circuits connected to the gate lines connected to the pixel circuits being charged are not charged or measured until the charge of the pixel circuit being charged is measured, and
when any of the first, second, third, and fourth pixel circuits is being measured, the other pixel circuits connected to the data lines connected to the pixel circuits being measured are not charged.

10. The measurement method according to claim 1, wherein said TFT array has a two-way shift register.

11. A method for measuring the holding properties of a TFT array of an active matrix display panel that comprises multiple pixel circuits with holding capacitors wherein each of the multiple pixel circuits comprises a holding capacitor, a switching transistor for connecting data lines with the holding capacitor, and a gate line for controlling the switching operation of the switching transistor, and these multiple pixel circuits consist of at least a first, second, third and fourth pixel circuit, said method comprising:
charging each pixel circuit of the first pixel group;
performing for each pixel circuit of both pixel groups a measurement of the charge from one of the pixel circuits of the first pixel group and charging of one of the pixel circuits of the second pixel group;
measuring the charge from each pixel circuit of the second pixel group; and
assigning each of the circuits of the first and second pixel groups so that the gate lines and data lines are different.

12. The method according to claim 11, wherein each of the circuits of the first and second pixel groups is assigned so that the gate lines and data lines are different and is a pixel circuit connected to a data line or a gate line connected to a pixel circuit whose charge has been measured, and a different pixel circuit connected to this data line or gate line then charges an uncharged pixel circuit.

13. The method according to claim 11, wherein said TFT array has a two-way shift register.
